(19) United States
(12) Patent Application Publication
(10) Pub. No.: US 2021/0390895 A1
(43) Pub. Date: Dec. 16, 2021

(54) GOA UNIT AND GOA CIRCUIT THEREOF, AND DISPLAY DEVICE

(71) Applicant: SHENZHEN ROYOLE TECHNOLOGIES CO., LTD., Shenzhen (CN)

(72) Inventors: Shaowen WANG, Shenzhen (CN); Ximeng Guan, Shenzhen (CN)

(21) Appl. No.: 17/358,835

(22) Filed: Jun. 25, 2021

Related U.S. Application Data
(63) Continuation of application No. PCT/CN2018/125066, filed on Dec. 28, 2018.

(51) Int. Cl. G09G 3/20

(52) U.S. Cl. CPC G09G 3/20; G09G 2300/0408; G09G 2310/08; G09G 2300/0809

(57) ABSTRACT

GOA unit and GOA circuit thereof, and display device. The GOA unit comprises a pull-up control module, a turn-on module, a pull-down and holding module, and a bootstrap capacitor, where an output end of the pull-up control module is connected to an input end of the turn-on module, an input end of the pull-down and holding module, and one end of the bootstrap capacitor; the input end of the turn-on module is connected to one end of the bootstrap capacitor, an output end of the turn-on module is connected to the other end of the bootstrap capacitor and an output end of the pull-down and holding module, the output end of the turn-on module is an output end of the GOA unit, the turn-on module and the pull-down and holding module include different types of thin film transistors, so a narrow bezel and a good display quality can be implemented.

### CROSS-REFERENCE TO RELATED APPLICATION

This application is a continuation of International Disclosure No. PCT/CN2018/125066, filed on Dec. 28, 2018. The disclosures of the aforementioned disclosures are hereby incorporated by reference in their entireties

### TECHNICAL FIELD

The present invention relates to the field of display technologies, and in particular, to a GOA unit and a GOA circuit thereof and a display device.

### BACKGROUND

A gate driver on array (GOA) circuit is widely used in electronic displays such as LCDs and AMOLEDs. As a key part of a display panel, the GOA circuit is used to provide scanning pulse signals to a pixel matrix.

At present, the GOA circuits on the market generally include multiple cascaded GOA units, and each GOA unit generally includes multiple thin film transistors (TFTs). In the prior art, the TFTs in the GOA unit are usually either all N-type TFTs or all P-type TFTs. However, if the TFTs are all N-type TFTs, because N-type TFTs are characterized by small mobility, a small driving current and poor stability but need to output a large current to a scan line, a relatively large area is needed for the TFTs in order to meet the requirements, which leads to an increase in an area occupied by the N-type TFTs and makes it difficult for a display panel to implement a narrow bezel design. If the TFTs are all P-type TFTs, because P-type TFTs have a relatively large leakage current, a TFT connected to a scan line is easily turned on or off improperly; consequently, the scan line electrically connected to the GOA unit outputs an error signal, and a pixel capacitor electrically connected to the scan line is improperly charged or discharged, which further leads to a display problem of the display panel.

### SUMMARY

An objective of to be addressed by the embodiments of the present invention is to provide a GOA unit and a GOA circuit thereof, and a display device against the above-mentioned defects in the prior art.

To solve the technical problems above, an embodiment of a first aspect of the present invention provides a GOA unit, which includes a pull-up control module, a turn-on module, a pull-down and holding module, and a bootstrap capacitor; where

an output end of the pull-up control module is electrically connected to an input end of the turn-on module, an input end of the pull-down and holding module, and one end of the bootstrap capacitor, respectively; and

the input end of the turn-on module is electrically connected to one end of the bootstrap capacitor, an output end of the turn-on module is electrically connected to the other end of the bootstrap capacitor and an output end of the pull-down and holding module, respectively, the output end of the turn-on module is an output end of the GOA unit, and the turn-on module and the pull-down and holding module include different types of thin film transistors.

An embodiment of a second aspect of the present invention provides a GOA circuit, including multiple cascaded GOA units, where an N^{th} stage GOA unit is the GOA unit described above, and N is an integer greater than or equal to 1.

An embodiment of a third aspect of the present invention provides a display device, including the GOA circuit described above.

The embodiments of the present invention have the following beneficial effects:

The turn-on module and the pull-down and holding module include different types of thin film transistors. Therefore, a current requirement of a scan line can be met without designing or occupying a large area because a turned-on P-type thin film transistor allows a relatively large current to pass through, which is beneficial to a narrow bezel design; and in addition, display quality is good because a turned-off N-type thin film transistor has a very small leakage current.

### BRIEF DESCRIPTION OF DRAWINGS

To describe the technical solutions in the embodiments of the present invention or in the prior art more clearly, the following briefly describes the accompanying drawings required for describing the embodiments or the prior art. Apparently, the accompanying drawings in the following description show merely some embodiments of the present invention, and a person of ordinary skill in the art may derive other accompanying drawings from these accompanying drawings without creative efforts.

FIG. 1 is a circuit diagram illustrating a GOA unit according to a first embodiment of the present invention;

FIG. 2 is a sequence diagram illustrating the GOA unit according to the first embodiment of the present invention;

FIG. 3 is a schematic diagram illustrating an output simulation result of the GOA unit according to the first embodiment of the present invention;

FIG. 4 is a schematic diagram illustrating a GOA circuit according to the first embodiment of the present invention;

FIG. 5 is a sequence diagram illustrating STV and CK1-CK4 in FIG. 4;

FIG. 6 is a schematic diagram illustrating an output simulation result of the GOA circuit according to the first embodiment of the present invention; and

FIG. 7 is a circuit diagram illustrating a GOA unit according to a second embodiment of the present invention.

Reference numerals in the drawings:

110, 210: pull-up control module; 120, 220: turn-on module; 130, 230: pull-down and holding module; 131, 231: pull-down branch; C1: bootstrap capacitor; T1 to T7: first to seventh thin film transistors; CLKB: first clock signal; CLKR: second clock signal; EN: enable signal; VGL: low-level signal; VGH: high-level signal; SC: scan line.

### DESCRIPTION OF EMBODIMENTS

The following clearly and completely describes the technical solutions in the embodiments of the present invention with reference to accompanying drawings in the embodiments of the present invention. Apparently, the described embodiments are merely some rather than all of the embodiments of the present invention. All other embodiments obtained by a person of ordinary skill in the art based on the embodiments of the present invention without creative efforts shall fall within the protection scope of the present invention.

The terms “including” and “having” and any variations thereof in the specification and the claims of the present application as well as the accompanying drawings are intended to cover non-exclusive inclusions. For example, a process, a method, a system, a product, or a device that includes a series of steps or units is not limited to the listed steps or units, but optionally further includes unlisted steps or units, or optionally further includes other steps or units inherent to the process, method, product or device. In addition, the terms “first”, “second”, and “third”, etc. are used to distinguish between different objects, rather than to describe a specific order.

### First Embodiment

This embodiment of the present invention provides a GOA unit.

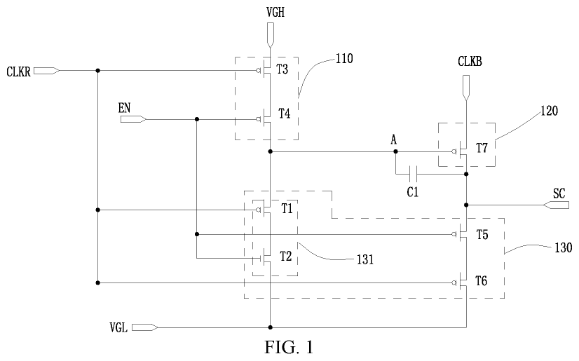

Referring to FIG. 1, the GOA unit includes a pull-up control module 110, a turn-on module 120, a pull-down and holding module 130, and a bootstrap capacitor C1.

In this embodiment, an output end of the pull-up control module 110 is electrically connected to an input end of the turn-on module 120, an input end of the pull-down and holding module 130, and a first end of the bootstrap capacitor C1, respectively. In this embodiment, the input end of the turn-on module 120 and the first end of the bootstrap capacitor C1 intersect at a point, i.e., a first node A in FIG. 1. In other words, the first node A is the input end of the turn-on module 120, and is also the first end of the bootstrap capacitor C1.

In this embodiment, the input end of the turn-on module 120 is electrically connected to the first end of the bootstrap capacitor C1, the output end of the pull-up control module 110, and the input end of the pull-down and holding module 130, respectively. An output end of the turn-on module 120 is electrically connected to a second end of the bootstrap capacitor C1 and an output end of the pull-down and holding module 130, respectively, and the output end of the turn-on module 120 is an output end of the GOA unit, and is used to electrically connect a scan line.

In this embodiment, the turn-on module 120 and the pull-down and holding module 130 include different types of thin film transistors. For example, the turn-on module 120 includes a P-type thin film transistor, and the pull-down and holding module 130 includes N-type thin film transistors. For another example, the turn-on module 120 includes an N-type thin film transistor, and the pull-down and holding module 130 includes P-type thin film transistors.

In this embodiment, the turn-on module 120 and the pull-down and holding module 130 include different types of thin film transistors. Therefore, a current requirement of the scan line can be met without designing or occupying a large area because a turned-on P-type thin film transistor allows a relatively large current to pass through, which is beneficial to a narrow bezel design; and in addition, display quality is good because a turned-off N-type thin film transistor has a very small leakage current.

Specifically, in this embodiment, the turn-on module 120 includes a seventh thin film transistor T7. The seventh thin film transistor T7 is a P-type thin film transistor. The gate of the seventh thin film transistor T7 is electrically connected to the first node A, i.e., the gate of the seventh thin film transistor T7 is the input end of the turn-on module 120. The source of the seventh thin film transistor T7 is electrically connected to a first clock signal CLKB. The drain of the seventh thin film transistor T7 is electrically connected to the scan line SC, i.e., the drain of the seventh thin film transistor T7 is the output end of the turn-on module 120. Therefore, when the seventh thin film transistor T7 is turned on, the first clock signal CLKB is output to the scan line SC via the seventh thin film transistor T7.

In this embodiment, the pull-down and holding module 130 includes at least one pull-down branch 131. The pull-down branch 131 includes a second thin film transistor T2. The second thin film transistor T2 is an N-type thin film transistor. The source of the second thin film transistor T2 is directly or indirectly electrically connected to the first node A and the output end of the pull-up control module 110, respectively. In this case, the source of the second thin film transistor T2 is indirectly electrically connected to the first node A and the output end of the pull-up control module 110, respectively. The drain of the second thin film transistor T2 is directly or indirectly electrically connected to a low-level signal line VGL. In this case, the drain of the second thin film transistor T2 is directly electrically connected to the low-level signal line VGL, and a low-level signal is transmitted on the low-level signal line VGL. The gate of the second thin film transistor T2 receives an enable signal EN. In addition, in another embodiment of the present invention, the pull-down and holding module may further include two, three or more pull-down branches, each pull-down branch includes one second thin film transistor, and the second thin film transistor is an N-type thin film transistor.

The seventh thin film transistor T7 in the turn-on module 120 is a P-type thin film transistor. Therefore, the current requirement of the scan line SC can be met without designing or occupying a large area for the seventh thin film transistor T7 because a turned-on P-type thin film transistor allows a relatively large current to pass through, which is beneficial to a narrow bezel design. In addition, the pull-down and holding module 130 includes the second thin film transistor T2, and the second thin film transistor T2 is an N-type thin film transistor. A turned-off N-type thin film transistor has a very small leakage current. Therefore, when the first node A is held at a high level, the first node A does not drop to a low level due to the leakage current, and the second thin film transistor T2 is not turned on improperly, thereby avoiding a display problem.

In this embodiment, the pull-down branch 131 further includes a first thin film transistor T1, and the second thin film transistor T2 is electrically connected to the first node A and the output end of the pull-up control module 110 via the first thin film transistor T1, respectively. The source of the first thin film transistor Ti is electrically connected to the first node A and the output end of the pull-up control module 110, respectively. In this case, the source of the first thin film transistor T1 is the input end of the pull-down and holding module 130. The drain of the first thin film transistor T1 is electrically connected to the source of the second thin film transistor T2. The gate of the first thin film transistor T1 receives a second clock signal CLKR, and the gate of the second thin film transistor T2 receives the enable signal EN. Therefore, the low-level signal line VGL sequentially passes through the second thin film transistor T2 and the first thin film transistor T1 to reach the first node A, which can further prevent the leakage current from improperly causing the first node A to drop to a low level when the first node A is at a high level. In this embodiment, the first thin film transistor T1 is a P-type thin film transistor, and the second thin film transistor T2 is an N-type thin film transistor.

In this embodiment, the pull-down and holding module 130 further includes a fifth thin film transistor T5 and a sixth thin film transistor T6. The source of the fifth thin film transistor T5 is electrically connected to the output end of the GOA unit, i.e., electrically connected to the scan line SC. In this case, the source of the fifth thin film transistor T5 is the output end of the pull-down and holding module 130. The drain of the fifth thin film transistor T5 is electrically connected to the source of the sixth thin film transistor T6. The gate of the fifth thin film transistor T5 receives the enable signal EN. The drain of the sixth thin film transistor T6 is electrically connected to the low-level signal line VGL. The gate of the sixth thin film transistor T6 receives the second clock signal CLKR. Therefore, when the fifth thin film transistor T5 and the sixth thin film transistor T6 are turned on, a low level on the low-level signal line VGL is output to the scan line SC, and the scan line SC is held at the low level, which can prevent the scan line SC from improperly transmitting a high level.

In this embodiment, the pull-up control module 110 includes a third thin film transistor T3 and a fourth thin film transistor T4. The source of the third thin film transistor T3 receives a high-level signal VGH. The drain of the third thin film transistor T3 is electrically connected to the source of the fourth thin film transistor T4. The gate of the third thin film transistor T3 receives the second clock signal CLKR. The drain of the fourth thin film transistor T4 is electrically connected to the first node A. In this case, the drain of the fourth thin film transistor T4 is the output end of the pull-up control module 110, and the gate of the fourth thin film transistor T4 receives the enable signal EN.

In this embodiment, the first thin film transistor T1 and the third thin film transistor T3 to the sixth thin film transistor T6 are P-type thin film transistors. However, the present invention is not limited thereto. In another embodiment of the present invention, the first thin film transistor and the third thin film transistor to the sixth thin film transistor may alternatively be N-type thin film transistors.

However, the present invention is not limited thereto. In another embodiment of the present invention, one of the third thin film transistor and the fourth thin film transistor is an N-type thin film transistor.

The following describes a specific operating time sequence of the GOA unit. In this embodiment, the GOA unit includes a first time period, a second time period, a third time period, a fourth time period, and a fifth time period in one time cycle, where the latter time period is adjacent to the previous one.

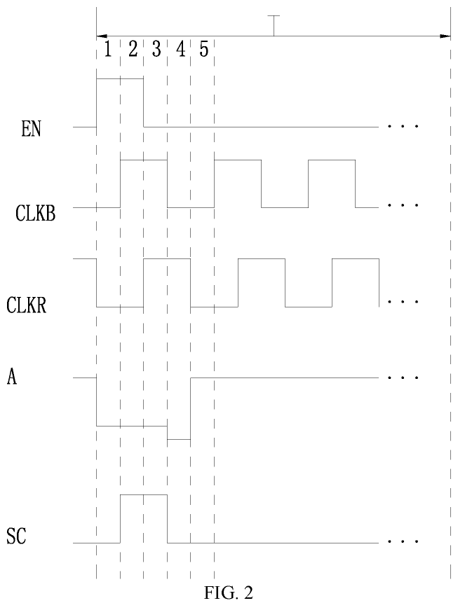

In this embodiment, referring to FIG. 1 and FIG. 2, in the first time period, the enable signal EN changes from a low level to a high level, the first clock signal CLKB continues to be held at a low level, and the second clock signal CLKR changes from a high level to a low level. In this case, the first thin film transistor T1, the second thin film transistor T2, the third thin film transistor T3, the sixth thin film transistor T6 and the seventh thin film transistor T7 are turned on, and the other thin film transistors are turned off. At this time, the first node A is connected to the low-level signal line VGL via the first thin film transistor T1 and the second thin film transistor T2. Therefore, the first node A is at a low level. Because the seventh thin film transistor T7 is a P-type thin film transistor, the seventh thin film transistor T7 is turned on, and the first clock signal CLKB is transmitted to the scan line SC.

In the second time period, the enable signal EN continues to be held at a high level, the first clock signal CLKB changes from the low level to a high level, and the second clock signal CLKR continues to be held at the low level. In this case, the first thin film transistor T1, the second thin film transistor T2, the third thin film transistor T3, the sixth thin film transistor T6 and the seventh thin film transistor T7 are turned on, and the other thin film transistors are turned off. At this time, the scan line SC outputs the first clock signal CLKB, i.e., the scan line SC outputs the high level. Therefore, a pixel thin film transistor in a display area that is electrically connected to the scan line SC is turned on, and a pixel capacitor is charged via a data line. Charging the pixel capacitor is a conventional technical means in the field, and is not described in detail here. At this point, the length of the second time period accounts for a ¼ cycle of the first clock signal CLKB.

In the third time period, the enable signal EN changes from the high level to a low level, the first clock signal CLKB is held at the high level, and the second clock signal CLKR changes from the low level to a high level. In this case, the fourth thin film transistor T4, the fifth thin film transistor T5 and the seventh thin film transistor T7 are turned on, the other thin film transistors are turned off, the first node A is suspended and held at the low level, and the scan line SC continues to output the high level. At this point, the length of the third time period accounts for a ¼ cycle of the first clock signal CLKB, and the cycle of the first clock signal CLKB is the same as that of the second clock signal CLKR.

In the fourth time period, the enable signal EN continues to be held at the low level, the first clock signal CLKB changes from the high level to a low level, and the second clock signal CLKR continues to be held at the high level. In this case, the fourth thin film transistor T4, the fifth thin film transistor T5 and the seventh thin film transistor T7 are turned on, respectively, and the other thin film transistors are turned off, respectively. The first node A drops to a level lower than the low level, and an electrical signal on the scan line SC is released by the seventh thin film transistor T7. At this point, the length of the fourth time period accounts for a ¼ cycle of the second clock signal CLKR.

In the fifth time period, the enable signal EN continues to be held at the low level, the first clock signal CLKB continues to be held at the low level, and the second clock signal CLKR changes from the high level to a low level. In this case, the first thin film transistor T1, the third thin film transistor T3, the fourth thin film transistor T4, the fifth thin film transistor T5 and the sixth thin film transistor T6 are turned on, respectively, and the other thin film transistors are turned off, respectively. The bootstrap capacitor C1 is charged, the first node A is at a high level, the seventh thin film transistor T7 is turned off, the scan line SC is electrically connected to the low-level signal line VGL via the fifth thin film transistor T5 and the sixth thin film transistor T6, and the scan line SC holds an output at a low level.

Afterwards, in a remaining time period of the cycle, the first clock signal CLKB and the second clock signal CLKR change between a high level and a low level periodically, the first node A is held at a high level, the seventh thin film transistor T7 and the second thin film transistor T2 are kept off, respectively, and the fourth thin film transistor T4 and the fifth thin film transistor T5 are kept on, respectively. The first thin film transistor T1, the third thin film transistor T3 and the sixth thin film transistor T6 are respectively turned off when the second clock signal CLKR is at a high level, and are respectively turned on when the second clock signal CLKR is at a low level, and the scan line SC outputs at a low level until the next cycle.

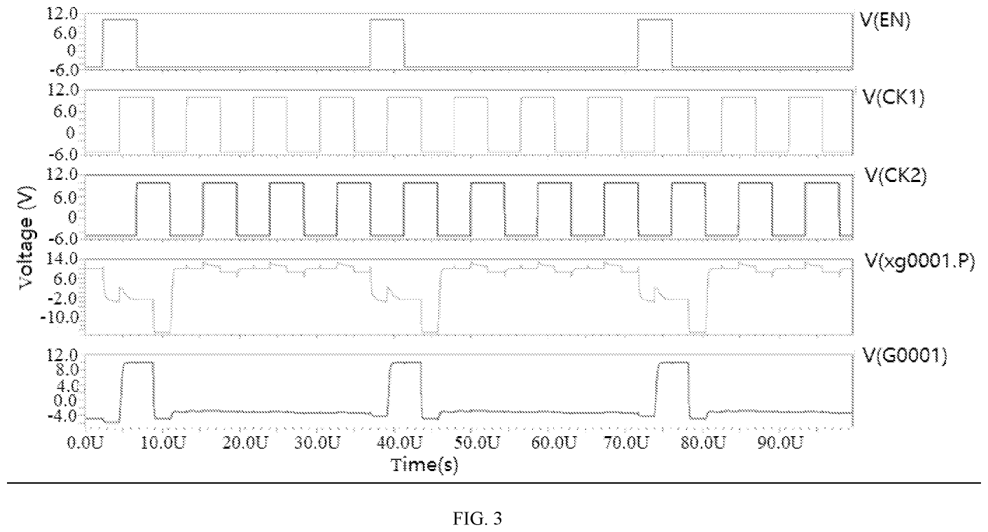

FIG. 3 is a schematic diagram illustrating an output simulation result of a single-stage GOA unit according to the first embodiment of the present invention. In FIG. 3, V (xg0001.P) is a voltage waveform at the first node A in the GOA unit of this embodiment, and V (G0001) is a voltage waveform that is output by the GOA unit of the present invention to the scan line (the output end of the GOA unit). It can be clearly seen that, a voltage at the first node A in the GOA unit of the present invention is relatively stable, the seventh thin film transistor T7 is not easily turned on or off improperly, an output voltage at the output end of the GOA unit is also relatively stable, and display quality is relatively good.

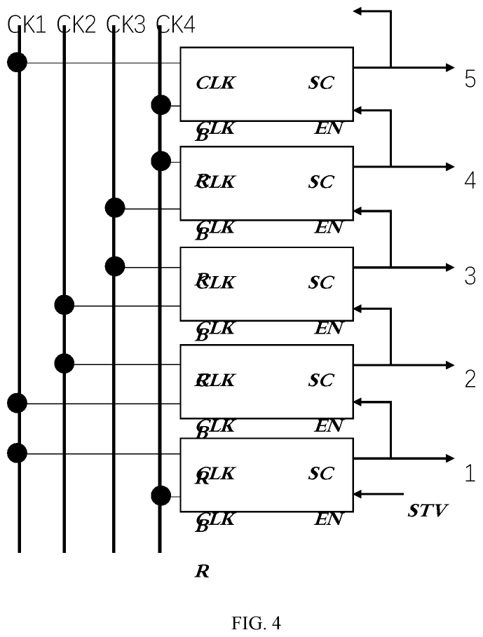

In addition, the present invention further provides a GOA circuit. Referring to FIG. 4, the GOA circuit includes multiple cascaded GOA units, where an N^{th} stage GOA unit is the GOA unit described above, and N is a positive integer greater than or equal to 1. In this embodiment, because a first clock signal and a second clock signal of adjacent first GOA units differ by a ¼ cycle, and waveforms of the first clock signal and the second clock signal are different, one GOA circuit needs at least 4 clock signals, for example, 4 clock signals, 6 clock signals, or 8 clock signals. In consideration of costs, in this embodiment, one GOA circuit needs 4 clock signals, which are CK1 to CK4.

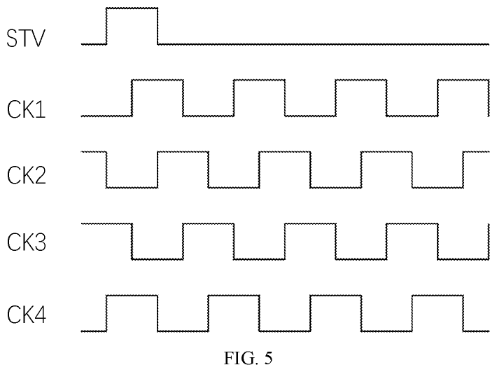

FIG. 4 illustrates a first GOA unit to a fifth GOA unit from bottom to top. A person skilled in the art can understand that there may further be GOA units above the fifth GOA unit, and the other GOA units are omitted here for ease of description. In this embodiment, STV is a start signal, and CK1, CK2, CK3 and CK4 are clock signals. For the time sequences of STV, CK1, CK2, CK3 and CK4, refer to FIG. 5. The clock signal CK1 is the first clock signal of the first GOA unit, and CK4 is the second clock signal of the first GOA unit; the clock signal CK2 is the first clock signal of the second GOA unit, and CK1 is the second clock signal of the second GOA unit; the clock signal CK3 is the first clock signal of the third GOA unit, and CK2 is the second clock signal of the third GOA unit; the clock signal CK4 is the first clock signal of the fourth GOA unit, and CK3 is the second clock signal of the fourth GOA unit; the clock signal CK1 is the first clock signal of the fifth GOA unit, and CK4 is the second clock signal of the fifth GOA unit; and connections between the clock signals and the following GOA units can be obtained by analogy. In addition, a person of ordinary skill in the art can understand that, in another embodiment of the present invention, the connections between the first clock signals and the second clock signals of the first GOA unit to the fourth GOA unit and CK1 to CK4 are not limited to the above-mentioned connection method. There may further be other connection methods. For example, the first clock signals of the first GOA unit to the fourth GOA unit are connected to CK2, CK3, CK4 and CK1, respectively, and the second clock signals of the first GOA unit to the fourth GOA unit are connected to CK1, CK2, CK3 and CK4, respectively; etc. The GOA circuit is a relatively conventional technology, which is not described in detail here.

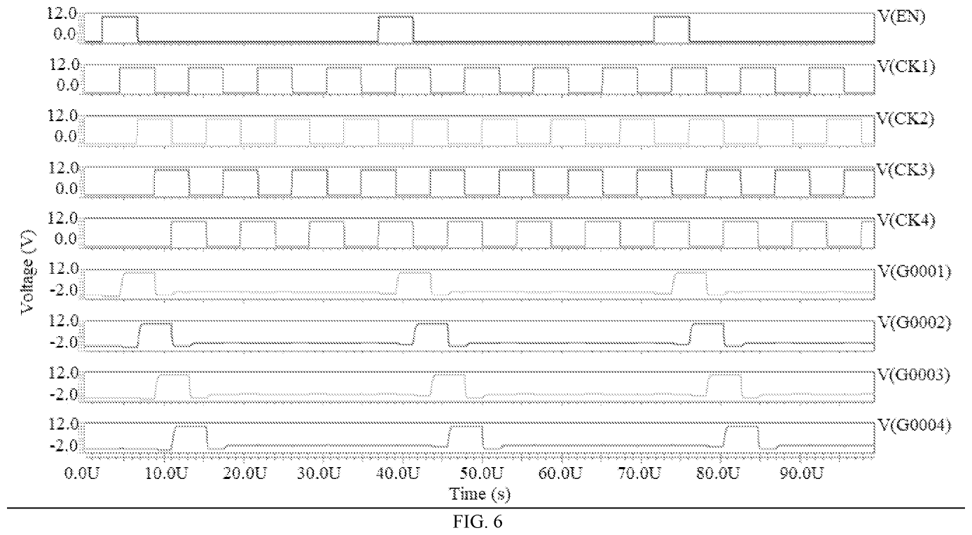

Refer to FIG. 6. In FIG. 6, V (G0001) is an output voltage waveform at an output end of the first GOA unit of the present invention, V (G0002) is an output voltage waveform at an output end of the second GOA unit of the present invention, V (G0003) is an output voltage waveform at an output end of the third GOA unit of the present invention, and V (G0004) is an output voltage waveform at an output end of the fourth GOA unit of the present invention. It is clearly seen from the figure that, output voltages at the output end of the first GOA unit, the output end of the second GOA unit, the output end of the third GOA unit, and the output end of the fourth GOA unit are stable.

In addition, the present invention further provides a display device, including the GOA circuit described above.

### Second Embodiment

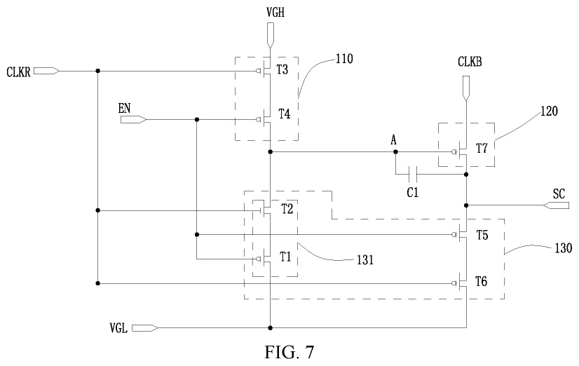

FIG. 7 is a circuit diagram illustrating a GOA unit according to the second embodiment of the present invention. The circuit in FIG. 7 is similar to the circuit in FIG. 1. Therefore, the same element signs represent the same components. This embodiment differs from the first embodiment mainly in that the positions of the first thin film transistor and the second thin film transistor are exchanged.

Referring to FIG. 7, in this embodiment, the pull-down and holding module 130 includes at least one pull-down branch 131. The pull-down branch 131 includes a second thin film transistor T2. The second thin film transistor T2 is an N-type thin film transistor. The source of the second thin film transistor T2 is directly or indirectly electrically connected to the first node A. In this case, the source of the second thin film transistor T2 is directly electrically connected to the first node A. At this point, the source of the second thin film transistor T2 is the input end of the pull-down and holding module 130. The drain of the second thin film transistor T2 is directly or indirectly electrically connected to the low-level signal line VGL. In this case, the drain of the second thin film transistor T2 is indirectly electrically connected to the low-level signal line VGL, and a low-level signal is transmitted on the low-level signal line VGL. The gate of the second thin film transistor T2 receives the second clock signal CLKR. In addition, in another embodiment of the present invention, the pull-down and holding module may further include two, three or more pull-down branches, each pull-down branch includes a second thin film transistor, and the second thin film transistor is an N-type thin film transistor.

In this embodiment, the pull-down branch further includes a first thin film transistor T1, and the second thin film transistor T2 is electrically connected to the low-level signal line VGL via the first thin film transistor T1. Specifically, the source of the first thin film transistor T1 is electrically connected to the drain of the second thin film transistor T2. The drain of the first thin film transistor T1 is electrically connected to the low-level signal line. The gate of the first thin film transistor T1 receives the enable signal EN. The first thin film transistor T1 is a P-type first thin film transistor.

It should be noted that the embodiments in the specification are described in a progressive manner, and each embodiment focuses on differences from other embodiments, and the same or similar parts between the embodiments can be referenced by each other. Because the device embodiment is substantially similar to the method embodiment, the description is relatively simple, and for the relevant parts, references may be made to part of the description of the method embodiment.

Disclosed above are only the preferred embodiments of the present invention, which certainly cannot be used to limit the scope of the claims of the present invention. Therefore, equivalent changes made according to the claims of the present invention still fall within the scope of the present invention.

What is claimed is:

1. A GOA unit, comprising a pull-up control module, a turn-on module, a pull-down and holding module, and a bootstrap capacitor, wherein
an output end of the pull-up control module is electrically connected to an input end of the turn-on module, an input end of the pull-down and holding module, and one end of the bootstrap capacitor, respectively; and
the input end of the turn-on module is electrically connected to one end of the bootstrap capacitor, an output end of the turn-on module is electrically connected to the other end of the bootstrap capacitor and an output end of the pull-down and holding module, respectively, the output end of the turn-on module is an output end of the GOA unit, and the turn-on module and the pull-down and holding module comprise different types of thin film transistors.

2. The GOA unit according to claim 1, wherein the turn-on module comprises a seventh thin film transistor, the seventh thin film transistor is a P-type thin film transistor, the gate of the seventh thin film transistor is electrically connected to the output end of the pull-up control module, the source of the seventh thin film transistor is electrically connected to a first clock signal, and the drain of the seventh thin film transistor is electrically connected to the output end of the GOA unit.

3. The GOA unit according to claim 1, wherein the pull-down and holding module comprises a pull-down branch, the pull-down branch comprises a second thin film transistor, the second thin film transistor is an N-type thin film transistor, the source of the second thin film transistor is directly or indirectly electrically connected to the output end of the pull-up control module, and the drain of the second thin film transistor is directly or indirectly electrically connected to a low-level signal line.

4. The GOA unit according to claim 3, wherein the pull-down and holding module further comprises a fifth thin film transistor and a sixth thin film transistor, the source of the fifth thin film transistor is electrically connected to the output end of the GOA unit, the drain of the fifth thin film transistor is electrically connected to the source of the sixth thin film transistor, the gate of the fifth thin film transistor receives an enable signal, the drain of the sixth thin film transistor is electrically connected to the low-level signal line, and the gate of the sixth thin film transistor receives a second clock signal.

5. The GOA unit according to claim 2, wherein the pull-up control module comprises a third thin film transistor and a fourth thin film transistor, the source of the third thin film transistor receives a high-level signal, the drain of the third thin film transistor is electrically connected to the source of the fourth thin film transistor, the gate of the third thin film transistor receives a second clock signal, the drain of the fourth thin film transistor is electrically connected to the input end of the turn-on module, and the gate of the fourth thin film transistor receives an enable signal.

6. The GOA unit according to claim 3, wherein the pull-down branch further comprises a first thin film transistor, the source of the first thin film transistor is electrically connected to the input end of the turn-on module, the drain of the first thin film transistor is electrically connected to the source of the second thin film transistor, the gate of the first thin film transistor receives a second clock signal, and the gate of the second thin film transistor receives an enable signal.

7. The GOA unit according to claim 3, wherein the pull-down branch further comprises a first thin film transistor, the source of the first thin film transistor is electrically connected to the drain of the second thin film transistor, the drain of the first thin film transistor is electrically connected to a low-level signal line, the gate of the first thin film transistor receives an enable signal, the gate of the second thin film transistor receives a second clock signal, and the source of the second thin film transistor is electrically connected to the input end of the turn-on module.

8. The GOA unit according to claim 6, wherein the first thin film transistor is a P-type thin film transistor.

9. The GOA unit according to claim 7, wherein the first thin film transistor is a P-type thin film transistor.

10. A GOA circuit, comprising multiple cascaded GOA units, wherein the N^{th} stage GOA unit is a GOA unit, and N is an integer greater than or equal to 1, the GOA unit, comprising a pull-up control module, a turn-on module, a pull-down and holding module, and a bootstrap capacitor, wherein
an output end of the pull-up control module is electrically connected to an input end of the turn-on module, an input end of the pull-down and holding module, and one end of the bootstrap capacitor, respectively; and
the input end of the turn-on module is electrically connected to one end of the bootstrap capacitor, an output end of the turn-on module is electrically connected to the other end of the bootstrap capacitor and an output end of the pull-down and holding module, respectively, the output end of the turn-on module is an output end of the GOA unit, and the turn-on module and the pull-down and holding module comprise different types of thin film transistors.

11. The GOA circuit according to claim 10, wherein the turn-on module comprises a seventh thin film transistor, the seventh thin film transistor is a P-type thin film transistor, the gate of the seventh thin film transistor is electrically connected to the output end of the pull-up control module, the source of the seventh thin film transistor is electrically connected to a first clock signal, and the drain of the seventh thin film transistor is electrically connected to the output end of the GOA unit.

12. The GOA circuit according to claim 10, wherein the pull-down and holding module comprises a pull-down branch, the pull-down branch comprises a second thin film transistor, the second thin film transistor is an N-type thin film transistor, the source of the second thin film transistor is directly or indirectly electrically connected to the output end of the pull-up control module, and the drain of the second thin film transistor is directly or indirectly electrically connected to a low-level signal line.

13. The GOA circuit according to claim 12, wherein the pull-down and holding module further comprises a fifth thin film transistor and a sixth thin film transistor, the source of the fifth thin film transistor is electrically connected to the output end of the GOA unit, the drain of the fifth thin film transistor is electrically connected to the source of the sixth thin film transistor, the gate of the fifth thin film transistor receives an enable signal, the drain of the sixth thin film transistor is electrically connected to the low-level signal line, and the gate of the sixth thin film transistor receives a second clock signal.

14. The GOA circuit according to claim 11, wherein the pull-up control module comprises a third thin film transistor and a fourth thin film transistor, the source of the third thin film transistor receives a high-level signal, the drain of the third thin film transistor is electrically connected to the source of the fourth thin film transistor, the gate of the third thin film transistor receives a second clock signal, the drain of the fourth thin film transistor is electrically connected to the input end of the turn-on module, and the gate of the fourth thin film transistor receives an enable signal.

15. The GOA circuit according to claim 12, wherein the pull-down branch further comprises a first thin film transistor, the source of the first thin film transistor is electrically connected to the input end of the turn-on module, the drain of the first thin film transistor is electrically connected to the source of the second thin film transistor, the gate of the first thin film transistor receives a second clock signal, and the gate of the second thin film transistor receives an enable signal.

16. The GOA circuit according to claim 12, wherein the pull-down branch further comprises a first thin film transistor, the source of the first thin film transistor is electrically connected to the drain of the second thin film transistor, the drain of the first thin film transistor is electrically connected to a low-level signal line, the gate of the first thin film transistor receives an enable signal, the gate of the second thin film transistor receives a second clock signal, and the source of the second thin film transistor is electrically connected to the input end of the turn-on module.

17. The GOA circuit according to claim 15, wherein the first thin film transistor is a P-type thin film transistor.

18. The GOA circuit according to claim 16, wherein the first thin film transistor is a P-type thin film transistor.

19. A display device, comprising the GOA circuit according to claim 10.
